(19) United States
(12) Patent Application Publication
(10) Pub. No.: US 2017/0092795 A1
(43) Pub. Date: Mar. 30, 2017

(54) INTERCONNECTOR AND SOLAR PANEL

(71) Applicants: KABUSHIKI KAISHA TOYOTA JIDOSHOKKI, Kariya-shi (JP); TOYOTA JIDOSHA KABUSHIKI KAISHA, Toyota-shi (JP)

(72) Inventors: Hirotaka INABA, Kariya-shi (JP); Kazutaka KIMURA, Susono-shi (JP)

(73) Assignees: KABUSHIKI KAISHA TOYOTA JIDOSHOKKI, Kariya-shi (JP); TOYOTA JIDOSHA KABUSHIKI KAISHA, Toyota-shi (JP)

(21) Appl. No.: 15/275,544

(22) Filed: Sep. 26, 2016

(30) Foreign Application Priority Data
Sep. 28, 2015 (JP) 2015-189661

(51) Int. Cl. H01L 31/05; H01L 31/049

(52) U.S. Cl. CPC H01L 31/0504; H01L 31/049

(57) ABSTRACT

An interconnector includes a first electrode connected to a first photovoltaic battery cell, a second electrode connected to a second photovoltaic battery cell, and a connection body that connects the first electrode and the second electrode. The connection body includes a detour portion that projects in a thickness-wise direction of the first electrode and the second electrode and a connection portion that extends in the first direction and is connected to the detour portion. The detour portion includes a first detour portion that is electrically connected to the first electrode and extended toward the first side in the second direction and a second detour portion that is electrically connected to the second electrode and extended toward the first side in the second direction. The connection portion includes a first connection portion that connects the first detour portion and the second detour portion.

### BACKGROUND OF THE INVENTION

The present invention relates to an interconnector and a solar panel.

Japanese Laid-Open Patent Publication No. 2005-191479 discloses a conventional solar panel including a protection cover, a back cover, a first photovoltaic battery cell, a second photovoltaic battery cell, an interconnector, and an encapsulant.

The protection cover is formed from inorganic glass and is translucent from the front surface to the rear surface. The back cover is formed by a resin film or the like. The first photovoltaic battery cell and the second photovoltaic battery cell are adjacent to each other in a first direction.

The interconnector is flat. The interconnector is arranged to be horizontal to the first photovoltaic battery cell and the second photovoltaic battery cell between the first photovoltaic battery cell and the second photovoltaic battery cell. The interconnector includes a first electrode connected to the first photovoltaic battery cell, a second electrode connected to the second photovoltaic battery cell, and a connection portion that connects the first electrode and the second electrode to each other. The encapsulant is located between the protection cover and the back cover to fix the first photovoltaic battery cell, the second photovoltaic battery cell, and the interconnector in an encapsulated state.

In the solar panel, the interconnector electrically connects the first photovoltaic battery cell and the second photovoltaic battery cell, which are adjacent to each other in the first direction.

Temperature changes expand and contract such a solar panel during manufacturing and use. This changes the interval between the adjacent first and second photovoltaic battery cells. Thus, in the conventional solar panel, when a temperature change causes contraction, the interval narrows between the first and second photovoltaic battery cells. Accordingly, the first and second photovoltaic battery cells press opposite sides of the interconnector and apply load to the interconnector. The load may break the interconnector in the thickness-wise direction. When a temperature change causes expansion, the interval widens between the first and second photovoltaic battery cells. Accordingly, the first and second photovoltaic battery cells pull the opposite sides of the interconnector and apply load to the interconnector. The load may separate the first electrode from the first photovoltaic battery cell or separate the second electrode from the second photovoltaic battery cell.

As a result, electrical connection between the first photovoltaic battery cell and the second photovoltaic battery cell may be impeded in the solar panel. In particular, when the protection cover and the back cover are formed from a resin, the above problem becomes more prominent.

### SUMMARY OF THE INVENTION

It is an object of the present invention to provide an interconnector and a solar panel that reduce the occurrence of defective electrical connections between the first photovoltaic battery cell and the second photovoltaic battery cell even when temperature changes cause expansion and contraction.

One aspect of the present invention provides an interconnector configured to connect a first photovoltaic battery cell and a second photovoltaic battery cell that are adjacent to each other in a first direction in a manner allowing for electrical connection of the first photovoltaic battery cell and the second photovoltaic battery cell. The interconnector includes a first electrode configured to be connected to the first photovoltaic battery cell, a second electrode configured to be connected to the second photovoltaic battery cell, and a connection body that connects the first electrode and the second electrode. A second direction is defined orthogonal to the first direction, and a first side and a second side are defined in the second direction. The first electrode, the second electrode, and the connection body are integrally formed by bending a single metal plate. The connection body includes a detour portion that projects in a thickness-wise direction of the first electrode and the second electrode and a connection portion that extends in the first direction and is connected to the detour portion. The detour portion includes a first detour portion that is electrically connected to the first electrode and extended toward the first side in the second direction and a second detour portion that is electrically connected to the second electrode and extended toward the first side in the second direction. The connection portion includes a first connection portion that connects the first detour portion and the second detour portion.

Another aspect of the present invention provides a solar panel. The solar panel includes a first photovoltaic battery cell, a second photovoltaic battery cell adjacent to the first photovoltaic battery cell in a first direction, an interconnector configured to connect the first photovoltaic battery cell and the second photovoltaic battery cell to each other in a manner allowing for electrical connection of the first photovoltaic battery cell and the second photovoltaic battery cell, a protection cover that is translucent from a front surface to a rear surface, a back cover, and an encapsulant that encapsulates and fixes the first photovoltaic battery cell, the second photovoltaic battery cell, and the interconnector between the protection cover and the back cover. The interconnector includes a first electrode configured to be connected to the first photovoltaic battery cell, a second electrode configured to be connected to the second photovoltaic battery cell, and a connection body that connects the first electrode and the second electrode. A second direction is defined orthogonal to the first direction, and a first side and a second side are defined in the second direction. The first electrode, the second electrode, and the connection body are integrally formed by bending a single metal plate. The connection body includes a detour portion that projects in a thickness-wise direction of the first electrode and the second electrode and a connection portion that extends in the first direction and is connected to the detour portion. The detour portion includes a first detour portion that is electrically connected to the first electrode and extended toward the first side in the second direction and a second detour portion that is electrically connected to the second electrode and extended toward the first side in the second direction. The connection portion includes a first connection portion that connects the first detour portion and the second detour portion.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a top view showing a first embodiment of a solar panel;

FIG. 2 is an enlarged cross-sectional view of the solar panel of the first embodiment taken along line A-A in FIG. 1;

FIG. 3 is an enlarged top view showing a first photovoltaic battery cell, a second photovoltaic battery cell, and an interconnector of the solar panel of the first embodiment;

FIG. 4 is a net diagram showing the interconnector of the solar panel of the first embodiment;

FIG. 5 is a perspective view showing the interconnector of the solar panel of the first embodiment;

FIG. 6 is a cross-sectional view showing a preparation step in a manufacturing process of the solar panel of the first embodiment;

FIG. 7 is a cross-sectional view showing an encapsulation step in the manufacturing process of the solar panel of the first embodiment;

FIG. 8 is a cross-sectional view showing a lamination step in the manufacturing process of the solar panel of the first embodiment;

FIG. 9 is an enlarged top view showing the first photovoltaic battery cell, the second photovoltaic battery cell, and the interconnector when the solar panel of the first embodiment contracts;

FIG. 10 is an enlarged top view showing the first photovoltaic battery cell, the second photovoltaic battery cell, and the interconnector when the solar panel of the first embodiment expands;

FIG. 11 is a perspective view showing an interconnector in a second embodiment of the solar panel;

FIG. 12 is a net diagram showing the interconnector in the solar panel of the second embodiment;

FIG. 13 is a perspective view showing an interconnector in a third embodiment of the solar panel;

FIG. 14 is a perspective view showing an interconnector in a fourth embodiment of the solar panel;

FIG. 15A is a cross-sectional view schematically showing the first photovoltaic battery cell, the second photovoltaic battery cell, and the interconnector in the same direction as FIG. 2 in the solar panel of the fourth embodiment when the first photovoltaic battery cell and the second photovoltaic battery cell are spaced apart by interval W1;

FIG. 15B is a cross-sectional view schematically showing the first photovoltaic battery cell, the second photovoltaic battery cell, and the interconnector when the first photovoltaic battery cell and the second photovoltaic battery cell are spaced apart by interval W2; and

FIG. 15C is a cross-sectional view schematically showing the first photovoltaic battery cell, the second photovoltaic battery cell, and the interconnector when the first photovoltaic battery cell and the second photovoltaic battery cell are spaced apart by interval W3.

### DETAILED DESCRIPTION OF THE PREFERRED EMBODIMENTS

First to fourth embodiments will now be described with reference to the drawings.

### First Embodiment

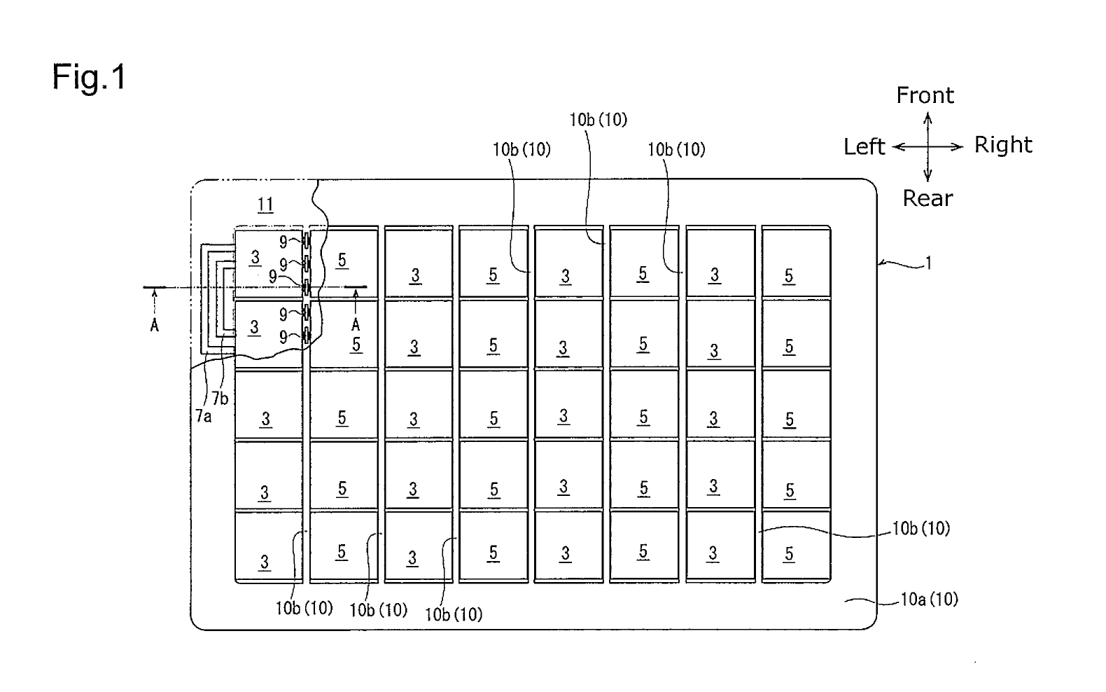

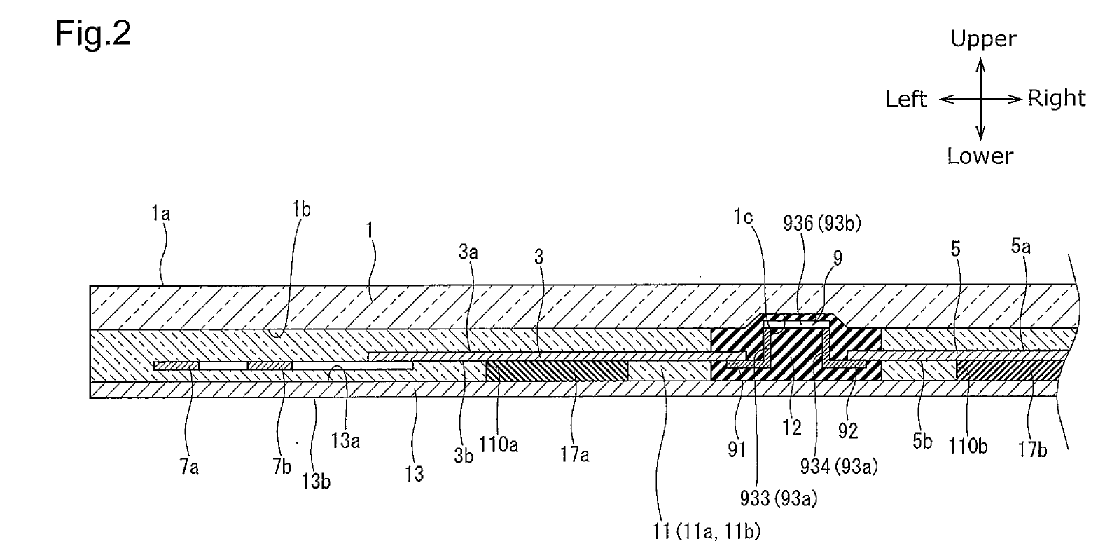

As shown in FIG. 1, a solar panel of the first embodiment includes a protection plate 1, first photovoltaic battery cells 3, second photovoltaic battery cells 5, tab wires 7a and 7b, interconnectors 9, an encapsulant 11, and a back panel 13, which is shown in FIG. 2. The protection plate 1 corresponds to a protection cover, and the back panel 13 corresponds to a back cover. To facilitate understanding, the protection plate 1 is not shown in the portion illustrated by broken lines in FIG. 1.

In the present embodiment, the arrows in FIG. 1 indicate the left, right, front, and rear directions of the solar panel. The direction extending from the left to the right is orthogonal to the direction extending from the front to the rear. The directions in the other drawings such as FIG. 2 correspond to the directions shown in FIG. 1, and the thickness-wise direction of the solar panel defines the vertical direction. The left-to-right (lateral) direction of the solar panel corresponds to a first direction. More specifically, the left direction corresponds to a first side of the first direction, and the right direction corresponds to a second side of the first direction. The front-to-rear direction of the solar panel corresponds to a second direction. More specifically, the rear direction corresponds to a first side of the second direction, and the front direction corresponds to a second side of the second direction. The directions of the solar panel are merely examples and irrelevant to the directions during use of the solar panel.

Referring to FIG. 2, the protection plate 1 is formed from a resin, the main component of which is polycarbonate. The protection plate 1 is translucent from a front surface 1a to a rear surface 1b. The front surface 1a of the protection plate 1 serves as a front surface of the solar panel, that is, a design surface of the solar panel. The front surface 1a is flat and horizontal, and the rear surface 1b is flat and parallel to the front surface 1a. Thus, the protection plate 1 is rectangular as shown in FIG. 1.

Further, a recess 1c is formed in a portion of the rear surface 1b of the protection plate 1 that opposes a connection body 93 (described below) of the interconnector 9. The recess 1c is recessed from the rear surface 1b toward the front surface 1a to extend away from the connection body 93. The depth of the recess 1c is set so that the connection body 93 does not contact the protection plate 1. The protection plate 1 may be formed from another resin or by an inorganic glass member. The protection plate 1 may be designed to have a suitable thickness.

The protection plate 1 includes a shield 10. The shield 10 includes a main portion 10a and connection portions 10b. The main portion 10a conceals the tab wires 7a and 7b from the front surface 1a of the protection plate 1. The connection portions 10b conceal the interconnectors 9 from the front surface 1a.

The main portion 10a and the connection portions 10b are formed by painting or printing an opaque color such as black to predetermined portions in the rear surface 1b of the protection plate 1. More specifically, the main portion 10a is located in the region of the protection plate 1 at the outer side of the first photovoltaic battery cells 3 and the second photovoltaic battery cells 5 and has the form of a frame that surrounds the first photovoltaic battery cells 3 and the second photovoltaic battery cells 5. The connection portions 10b are located at the inner side of the main portion 10a. The connection portions 10b extend in the front-to-rear direction of the protection plate 1 and are continuous with a front side and a rear side of the main portion 10a. The number of the connection portions 10b corresponds to the number of intervals between the first photovoltaic battery cells 3 and the second photovoltaic battery cells 5 that are adjacent to one another in the lateral direction. Further, the width of each connection portion 10b corresponds to the size of each interval between the first photovoltaic battery cells 3 and the second photovoltaic battery cells 5 that are adjacent to one another in the lateral direction. To facilitate understanding, the shield 10 is not shown in FIGS. 2 and 6 to 8.

Referring to FIG. 2, crystalline silicon is used in the first photovoltaic battery cells 3 and the second photovoltaic battery cells 5. The first photovoltaic battery cells 3 and the second photovoltaic battery cells 5 each have the same structure and exhibit the same performance. More specifically, each first photovoltaic battery cell 3 is a thin film and includes a front surface 3a and a rear surface 3b. In the same manner, each second photovoltaic battery cell 5 is a thin film and includes a front surface 5a and a rear surface 5b. Conductors (not shown) are arranged on the rear surface 3b of the first photovoltaic battery cell 3 and the rear surface 5b of the second photovoltaic battery cell 5.

The tab wires 7a and 7b, each formed by a thin metal plate, are arranged at the right side or the left side of the solar panel at a fixed interval. The tab wires 7a and 7b electrically connect the first photovoltaic battery cells 3 and the second photovoltaic battery cells 5 of different lines in the front-to-rear direction. The form and number of the tab wires 7a and 7b may be changed. Further, the locations where the tab wires 7a and 7b are connected to the first and second photovoltaic battery cells 3 and 5 may be changed.

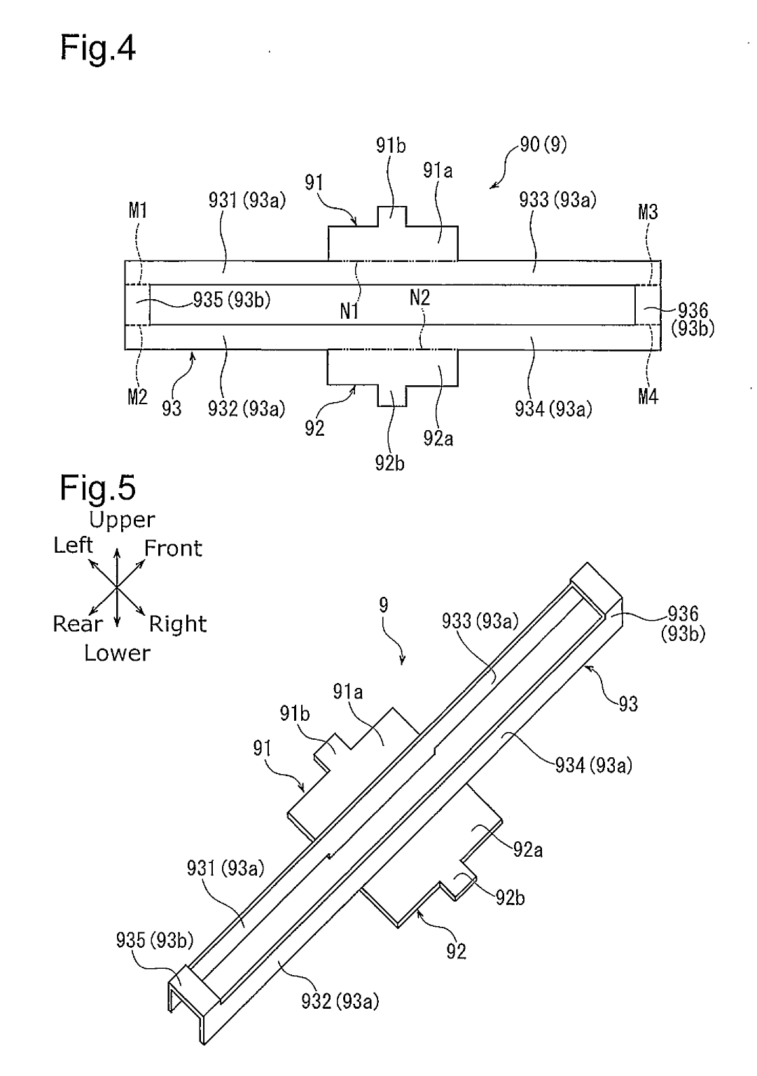

Each interconnector 9 is formed from a copper plate 90, which is shown in FIG. 4. The copper plate 90 corresponds to a metal plate. When forming the interconnector 9, the copper plate 90 is first punched into the shape shown in the net diagram of FIG. 4. Then, the copper plate 90 is bent. More specifically, mountain-folding (bending) is performed at a substantially right angle at bent positions M1 to M4, which are shown by broken lines in FIG. 4. Further, valley-folding (bending) is performed at a substantially right angle at bent positions N1 and N2, which are shown by the double-dashed lines in FIG. 4. The copper plate 90 is one example. Instead, a metal plate other than the copper plate 90 may be bent to form the interconnector 9. However, a bimetal plate cannot be used as the metal plate.

The interconnector 9, which is formed in such a manner, includes a first electrode 91, a second electrode 92, and the connection body 93 as shown in FIG. 5. The first electrode 91, the second electrode 92, and the connection body 93 are integrally formed.

The first electrode 91 is located at the left side of the interconnector 9, and the second electrode 92 is located at the right side of the interconnector 9. The first electrode 91 includes a first base 91a, which extends in the front-to-rear direction of the interconnector 9, and a first contact 91b, which is integrated with the first base 91a and extended from the first base 91a toward the left side. The second electrode 92 includes a second base 92a, which extends in the front-to-rear direction of the interconnector 9, and a second contact 92b, which is integrated with the second base 92a and extended from the second base 92a toward the right side.

The connection body 93 includes a detour portion 93a and a connection portion 93b. More specifically, the detour portion 93a includes first to fourth detour portions 931 to 934. The connection portion 93b includes first and second connection portions 935 and 936.

Valley-folding (bending) is performed at the bent position N1, which is shown in FIG. 4, so that the first detour portion 931 projects at a substantially right angle toward the upper side in the thickness-wise direction of the first electrode 91 and a front end of the first detour portion 931 is integrated with the first base 91a of the first electrode 91 as shown in FIG. 5. The first detour portion 931 is a single piece having a predetermined width, that is, a predetermined height in the vertical direction, and extending toward a rear side of the interconnector 9.

Valley-folding (bending) is performed at the bent position N2, which is shown in FIG. 4, so that the second detour portion 932 projects at a substantially right angle toward the upper side in the thickness-wise direction of the second electrode 92 and a front end of the second detour portion 932 is integrated with the second base 92a of the second electrode 92 as shown in FIG. 5. The second detour portion 932 is spaced apart by a predetermined interval from the right side of the first detour portion 931. The second detour portion 932 is a single piece having the same width as the first detour portion 931 and extending toward the rear side of the interconnector 9.

Valley-folding (bending) is performed at the bent position N1, which is shown in FIG. 4, so that the third detour portion 933 projects at a substantially right angle toward the upper side in the thickness-wise direction of the first electrode 91 and a rear end of the third detour portion 933 is integrated with the first base 91a of the first electrode 91 as shown in FIG. 5. The third detour portion 933 is continuous with the front end of the first detour portion 931. The third detour portion 933 is a single piece having the same width as the first detour portion 931 and extending toward a front side of the interconnector 9. The first detour portion 931 may be non-continuous with the third detour portion 933.

Valley-folding (bending) is performed at the bent position N2, which is shown in FIG. 4, so that the fourth detour portion 934 projects at a substantially right angle toward the upper side in the thickness-wise direction of the second electrode 92 and a rear end of the fourth detour portion 934 is integrated with the second base 92a of the second electrode 92 as shown in FIG. 5. The fourth detour portion 934 is continuous with the front end of the second detour portion 932. The fourth detour portion 934 is a single piece having the same width as the first detour portion 931 and extending toward the front side of the interconnector 9. The second detour portion 932 may be non-continuous with the fourth detour portion 934.

Mountain-folding (bending) is performed at the bent portions M1 and M2, which are shown in FIG. 4, to form the first connection portion 935 between a rear end of the first detour portion 931 and a rear end of the second detour portion 932, that is, at a rear end of the connection body 93, as shown in FIG. 5. The first connection portion 935 is a single piece extending substantially horizontally in the lateral direction so that the first connection portion 935 is proximate to the rear end of the first detour portion 931 and the rear end of the second detour portion 932. A left end of the first connection portion 935 is continuous with the rear end of the first detour portion 931. Further, a right end of the first connection portion 935 is continuous with the rear end of the second detour portion 932. Thus, the first connection portion 935 connects the first detour portion 931 to the second detour portion 932.

In the same manner, mountain-folding (bending) is performed at the bent portions M3 and M4 of FIG. 4 to form the second connection portion 936. The second connection portion 936 connects a front end of the third detour portion 933 to a front end of the fourth detour portion 934.

In such a manner, in the interconnector 9, the first electrode 91 and the second electrode 92 are connected by the connection body 93 so that the first electrode 91 and the second electrode 92 are electrically connected to each other by the connection body 93, namely, the first to fourth detour portions 931 to 934 and the first and second connection portions 935 and 936. Further, the connection body 93 connects the first electrode 91 to the second electrode 92 as described above to define a void 94 that extends in the front-to-rear direction and the lateral direction at the middle of the interconnector 9. The void 94 functions as a separator that separates the first detour portion 931, the first electrode 91, and the third detour portion 933 from the second detour portion 932, the second electrode 92, and the fourth detour portion 934 in the lateral direction.

As described above, in the interconnector 9, mountain-folding (bending) is performed at the bent portions M1 to M4 of FIG. 4. Thus, as shown in FIG. 5, the first connection portion 935 is located toward the upper side from the first detour portion 931 and the second detour portion 932. In the same manner, the second connection portion 936 is located toward the upper side from the third detour portion 933 and the fourth detour portion 934. Accordingly, the first connection portion 935 and the second connection portion 936 are located at the uppermost position of the interconnector 9.

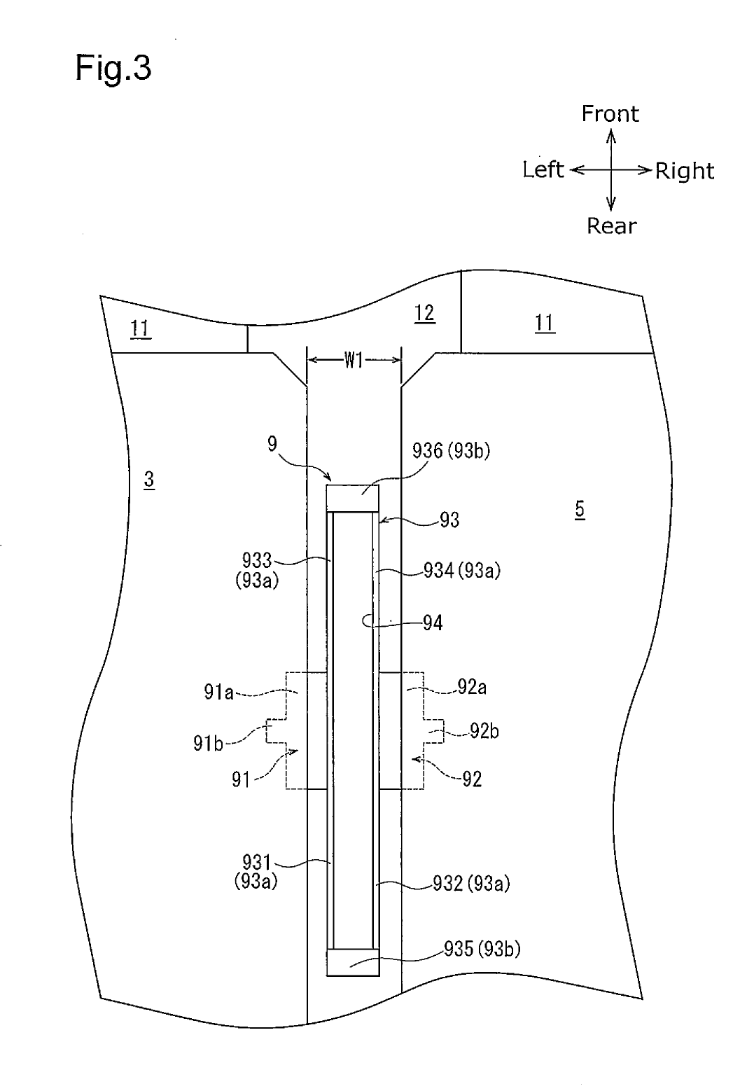

As shown in FIG. 1, in the solar panel, three interconnectors 9 electrically connect the first photovoltaic battery cell 3 to the second photovoltaic battery cell 5 that is adjacent in the lateral direction. As shown in FIG. 3, in each interconnector 9, the first electrode 91 is connected to the first photovoltaic battery cell 3 so that the conductor of the first photovoltaic battery cell 3 is electrically connected to the first contact 91b. Further, the second electrode 92 is connected to the second photovoltaic battery cell 5 so that the conductor of the second photovoltaic battery cell 5 is electrically connected to the second contact 92b. Since the conductors are arranged on the rear surfaces 3b and 5b of the first and second photovoltaic battery cells 3 and 5 as described above, the first electrode 91 is connected to the rear surface 3b of the first photovoltaic battery cell 3 as shown in FIG. 2. In the same manner, the second electrode 92 is connected to the rear surface 5b of the second photovoltaic battery cell 5. Further, since the first electrode 91 and the second electrode 92 are respectively connected to the first photovoltaic battery cell 3 and the second photovoltaic battery cell 5, the connection body 93 of the interconnector 9 projects upward from the front surfaces 3a and 5a of the first and second photovoltaic battery cells 3 and 5. To facilitate understanding, the form of the interconnector 9 is simplified in FIGS. 2 and 6 to 8.

Thus, as shown in FIG. 1, three interconnectors 9 are located between each set of the first photovoltaic battery cell 3 and the second photovoltaic battery cell 5. Further, as shown in FIG. 3, the first photovoltaic battery cell 3 and the second photovoltaic battery cell 5, which are electrically connected by the interconnector 9, are spaced apart from each other by interval W1. The number of the interconnectors 9 used to electrically connect each first photovoltaic battery cell 3 to the adjacent second photovoltaic battery cell 5 may be changed in accordance with the size and the like of the first photovoltaic battery cell 3 and the second photovoltaic battery cell 5.

Referring to FIG. 2, ethylene-vinyl acetate copolymer (EVA) is used for the encapsulant 11. The encapsulant 11 includes sheets of encapsulants 11a and 11b, which will be described below. The encapsulant 11 encapsulates and fixes each of the first and second photovoltaic battery cells 3 and 5, each of the tab wires 7a and 7b, and each of the interconnectors 9 between the protection plate 1 and the back panel 13, more specifically, between the rear surface 1b of the protection plate 1 and a front surface 13a of the back panel 13. Thus, the encapsulant 11 is integrated with the protection plate 1 and the back panel 13 to fix the first and second photovoltaic battery cells 3 and 5 and the like in an encapsulated state and protect the first and second photovoltaic battery cells 3 and 5 from oxygen and moisture, which cause deterioration.

A silicone resin 12 is arranged in the encapsulant 11. The silicone resin 12 surrounds each interconnector 9. The silicone resin 12 is elastically deformed to hold the entire interconnector 9, the right end of the corresponding first photovoltaic battery cell 3, and the left end of the corresponding second photovoltaic battery cell 5 in an encapsulated state. Further, the encapsulant 11 includes a first silicone resin 17a and a second silicone resin 17b, which will be described below. For example, an ionomer resin, a silicone resin, or a polyolefin may be used for the encapsulant 11 instead of EVA.

The back panel 13 is formed by a metal plate of an aluminum alloy or the like. The back panel 13 is rectangular and includes the front surface 13a and a rear surface 13b. The front surface 13a opposes the rear surface 1b of the protection plate 1, each of the first and second photovoltaic battery cells 3 and 5, and the encapsulant 11. The rear surface 13b is opposite to the front surface 13a. The back panel 13, which is arranged on the rear surface of the encapsulant 11, cooperates with the encapsulant 11 to protect the first and second photovoltaic battery cells 3 and 5 and the like from moisture and oxygen, which cause deterioration. When the protection plate 1 has insufficient rigidity, the back panel 13 ensures the rigidity of the solar panel. The back panel 13 may be formed from a resin such as carbon-fiber-reinforced plastic (CFRP). The protection plate 1 and the back panel 13 may both be formed from a resin and configured so that the protection plate 1 and the back panel 13 ensure the rigidity of the solar panel. When the protection plate 1 is rigid enough to obtain the rigidity of the solar panel, a thin film of polyetherketone (PEK) may be used as the back cover instead of the back panel 13.

The first and second silicone resins 17a and 17b respectively cause the first and second photovoltaic battery cells 3 and 5 to adhere to the back panel 13. More specifically, the first silicone resin 17a causes the front surface 13a of the back panel 13 to adhere to the rear surface 3b of each first photovoltaic battery cell 3, and the second silicone resin 17b causes the front surface 13a of the back panel 13 to adhere to the rear surface 5b of each second photovoltaic battery cell 5. The first silicone resin 17a corresponds to a first adhesive, and the second silicone resin 17b corresponds to a second adhesive. The first silicone resin 17a and the second silicone resin 17b may be formed from the same material. Alternatively, the first silicone resin 17a and the second silicone resin 17b may be formed from different materials under different conditions.

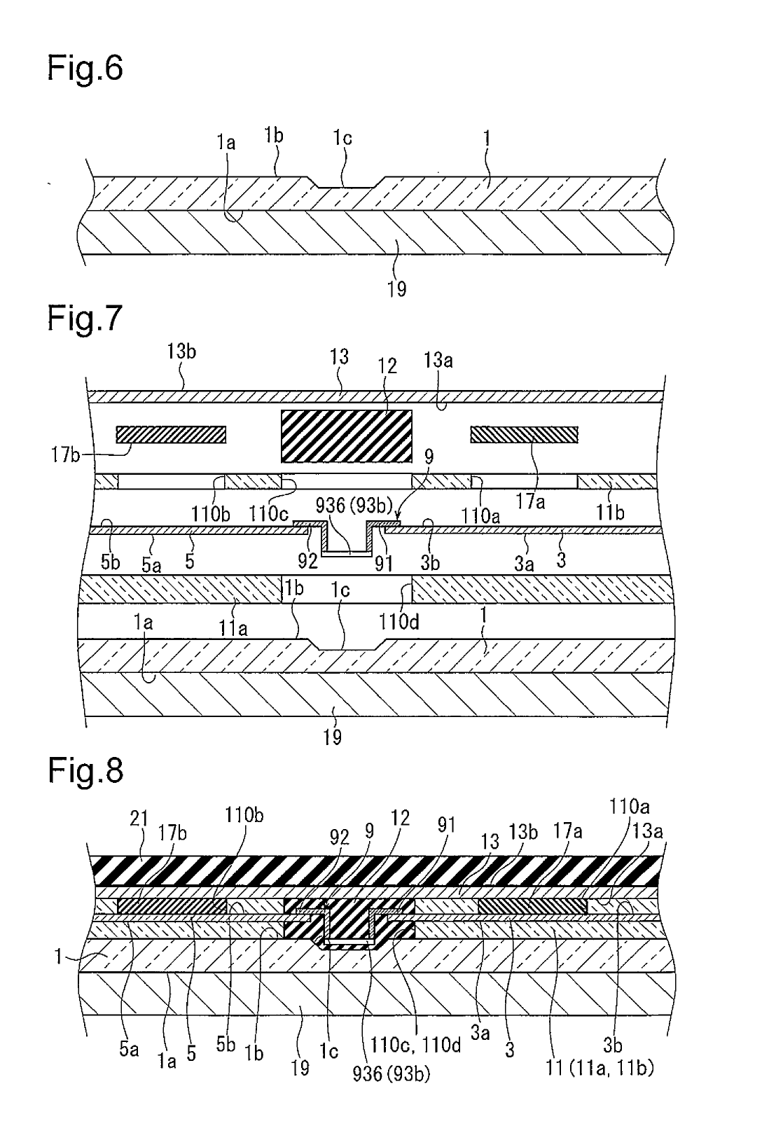

The solar panel is manufactured as follows. First, as shown in FIG. 6, in the preparation step, a vacuum molding jig 19 that can be heated is prepared. The protection plate 1 that has been formed in advance is mounted on the vacuum molding jig 19 so that the front surface 1a opposes the vacuum molding jig 19.

Then, as shown in FIG. 7, in the encapsulation step, the encapsulant 11a, each of the first and second photovoltaic battery cells 3 and 5, the tab wires 7a and 7b, each interconnector 9, and the encapsulant 11b are first arranged sequentially above the rear surface 1b of the protection plate 1. The first and second photovoltaic battery cells 3 and 5 are electrically connected to one another by the tab wires 7a and 7b and the interconnectors 9. When arranging the interconnectors 9, the first connection portion 935 and the second connection portion 936 are located in the recess 1c of the protection plate 1 to position the interconnectors 9 relative to the protection plate 1.

The encapsulant 11b includes first cutouts 110a and second cutouts 110b. The first cutouts 110a are located at positions opposing the rear surfaces 3b of the first photovoltaic battery cells 3, and the second cutouts 110b are located at positions opposing the rear surfaces 5b of the second photovoltaic battery cells 5. The number of the first cutouts 110a and the second cutouts 110b formed in the encapsulant 11b corresponds to the number of the first photovoltaic battery cells 3 and the second photovoltaic battery cells 5.

In addition, the encapsulant 11b includes third cutouts 110c. The third cutouts 110c are located between the first cutouts 110a and the second cutouts 110b at positions opposing the interconnectors 9. Further, fourth cutouts 110d are arranged in the encapsulant 11a at positions opposing the interconnector 9.

Each of the first cutouts 110a is filled with the first silicone resin 17a, and each of the second cutouts 110b is filled with the second silicone resin 17b. Further, the third cutouts 110c and the fourth cutouts 110d are filled with the silicone resin 12. Subsequently, the back panel 13 is arranged so that the front surface 13a opposes the rear surface 1b of the protection plate 1.

After the back panel 13 is arranged, the lamination step is performed. More specifically, as shown in FIG. 8, a diaphragm 21 is pressed toward the vacuum molding jig 19 and a vacuum state is produced between the vacuum molding jig 19 and the diaphragm 21, that is, between the vacuum molding jig 19 and the above members that form the solar panel. Further, the vacuum molding jig 19 is heated when pressed by the diaphragm 21 to soften the encapsulants 11a and 11b and cause the members to adhere to each other. Thus, each of the first photovoltaic battery cells 3 and 5, each of the tab wires 7a and 7b, and each interconnector 9 are fixed in an encapsulated state between the rear surface 1b of the protection plate 1 and the front surface 13a of the back panel 13. In addition, each interconnector 9, the right end of each first photovoltaic battery cell 3, and the left end of each second photovoltaic battery cell 5 are held by the silicone resin 12 in an encapsulated state. Further, each first silicone resin 17a causes each first photovoltaic battery cell 3 to adhere to the back panel 13, and each second silicone resin 17b causes each second photovoltaic battery cell 5 to adhere to the back panel 13. This forms the solar panel.

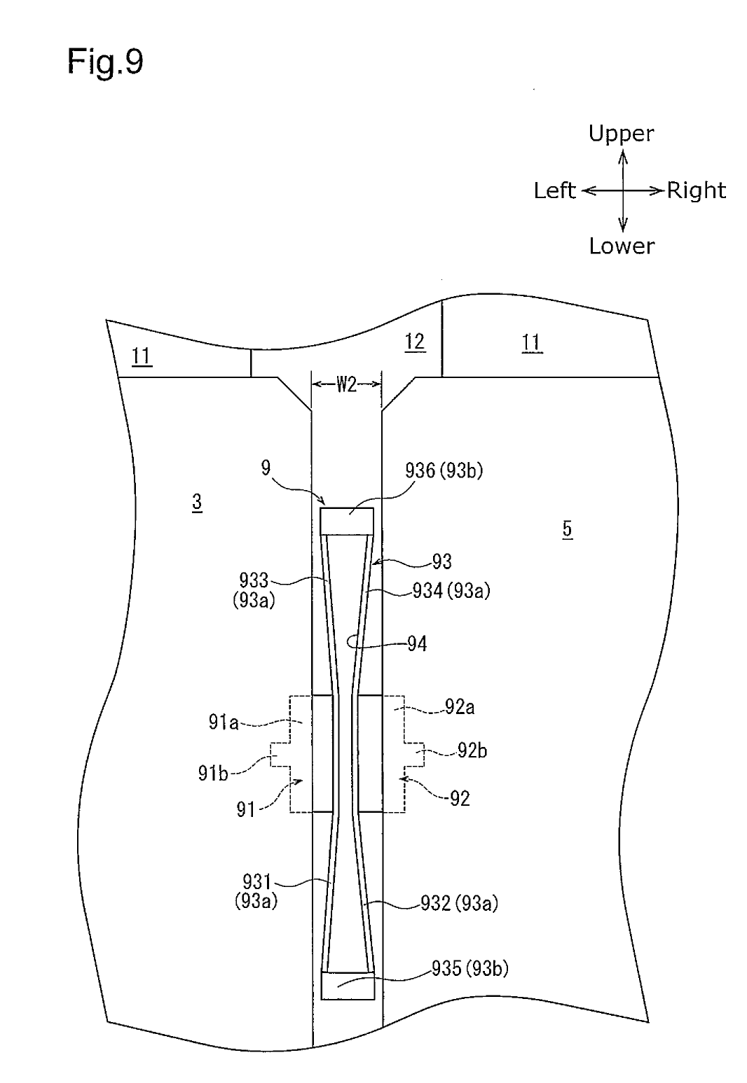

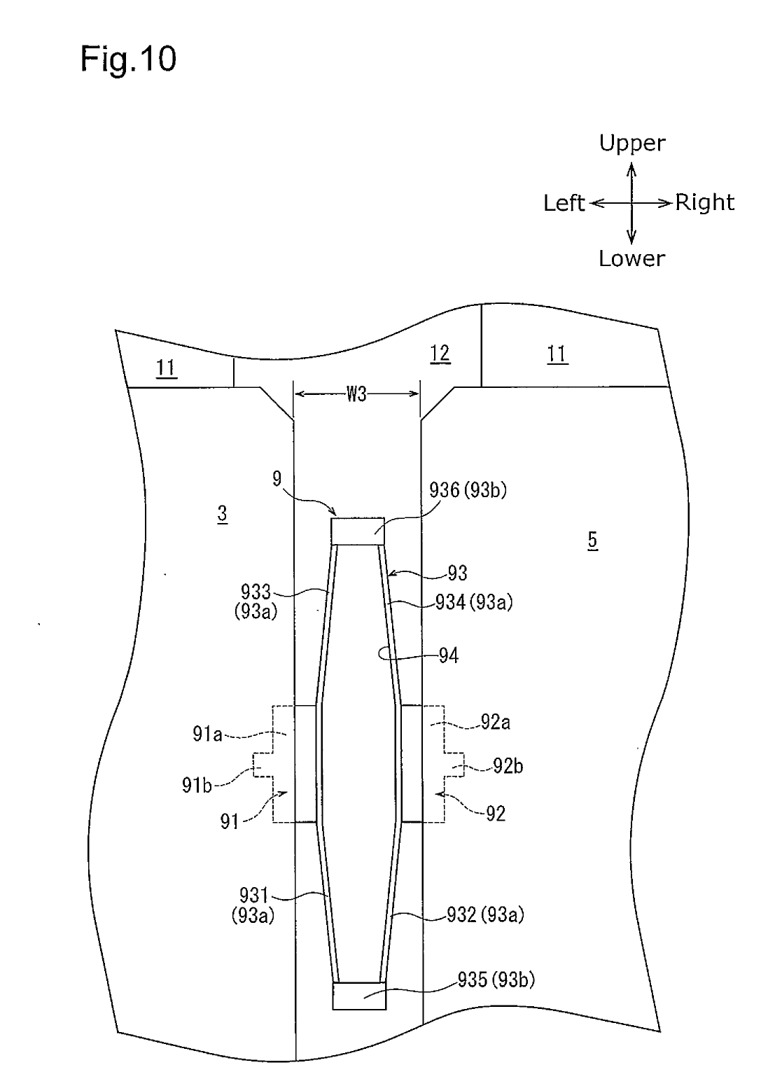

As shown in FIG. 1, in the solar panel, three interconnectors 9 electrically connect each first photovoltaic battery cell 3 to the adjacent second photovoltaic battery cell 5 in the lateral direction. As shown in FIG. 3, in each of the interconnectors 9, the first electrode 91 and the second electrode 92 are connected by the connection body 93. In the connection body 93, the first to fourth detour portions 931 to 934 project in the thickness-wise direction upward from the first electrode 91 and the second electrode 92. Thus, when temperature changes during manufacturing and use thermally expands or contracts the solar panel, the interval W1 shown in FIG. 3 between the first photovoltaic battery cell 3 and the second photovoltaic battery cell 5 changes to the interval W2 shown in FIG. 9 or the interval W3 shown FIG. 10. When the first to fourth detour portions 931 to 934 of the connection body 93 are deformed like a pantograph, the interval between the first electrode 91 and the second electrode 92 changes accordingly in each interconnector 9.

More specifically, as shown in FIG. 9, when the solar panel is contracted by temperature changes, the first photovoltaic battery cell 3 and the second photovoltaic battery cell 5 move toward each other in the lateral direction. In this case, the interval W2 between the first photovoltaic battery cell 3 and the second photovoltaic battery cell 5 is narrower than the interval W1 shown in FIG. 3. Accordingly, in the connection body 93 of each interconnector 9, as shown in FIG. 9, the first detour portion 931 and the second detour portion 932 are flexed in a thickness-wise direction of the first detour portion 931 and the second detour portion 932 and moved toward each other in the lateral direction from the states shown in FIGS. 3 and 5. In the same manner, the third detour portion 933 and the fourth detour portion 934 are flexed in a thickness-wise direction of the third detour portion 933 and the fourth detour portion 934 and moved toward each other in the lateral direction. Thus, the first electrode 91 and the second electrode 92 move toward each other in the lateral direction and narrow the middle void 94 of each interconnector 9 from the states shown in FIGS. 3 and 5.

When the interval of the first photovoltaic battery cell 3 and the second photovoltaic battery cell 5 is narrowed, each interconnector 9 absorbs the change. As a result, in each interconnector 9, the first electrode 91 and the second electrode 92 are movable toward each other in the lateral direction while the deformation of the first to fourth detour portions 931 to 934 absorbs the load of the pressing force applied in the lateral direction by the corresponding first photovoltaic battery cell 3 and the corresponding second photovoltaic battery cell 5 when the solar panel contracts. Thus, in the solar panel, even when the interval narrows between the first photovoltaic battery cell 3 and the second photovoltaic battery cell 5, breakage of the interconnector 9 in the thickness-wise direction that would be caused by the narrowed interval does not occur.

As shown in FIG. 10, when the solar panel is expanded by temperature changes, the first photovoltaic battery cell 3 and the second photovoltaic battery cell 5 move away from each other in the lateral direction. In this case, the interval W3 between the first photovoltaic battery cell 3 and the second photovoltaic battery cell 5 is wider than the interval W1 shown in FIG. 3. In the connection body 93 of each interconnector 9, as shown in FIG. 10, the first detour portion 931 and the second detour portion 932 are flexed in the thickness-wise direction of the first detour portion 931 and the second detour portion 932 and moved away from each other in the lateral direction from the states shown in FIGS. 3 and 5. That is, the first detour portion 931 and the second detour portion 932 are flexed in the thickness-wise direction of the first detour portion 931 and the second detour portion 932 that is opposite to when the first detour portion 931 and the second detour portion 932 move toward each other in the lateral direction. In the same manner, the third detour portion 933 and the fourth detour portion 934 are flexed in the thickness-wise direction of the third detour portion 933 and the fourth detour portion 934 and moved away from each other in the lateral direction. Thus, the first electrode 91 and the second electrode 92 move away from each other in the lateral direction and widen the middle void 94 of each interconnector 9 from the states shown in FIGS. 3 and 5.

When the interval of the first photovoltaic battery cell 3 and the second photovoltaic battery cell 5 is widened, each interconnector 9 absorbs the change. As a result, when the solar panel expands, in each interconnector 9, the first electrode 91 and the second electrode 92 are movable away from each other in the lateral direction while the deformation of the first to fourth detour portions 931 to 934 absorbs the load of the pulling force in the lateral direction applied by the corresponding first photovoltaic battery cell 3 and the corresponding second photovoltaic battery cell 5. Thus, in the solar panel, even when the interval widens between each first photovoltaic battery cell 3 and each second photovoltaic battery cell 5, separation of the first electrode 91 from the first photovoltaic battery cell 3 and separation of the second electrode 92 from the second photovoltaic battery cell 5 that would be caused by the widened interval do not occur.

Thus, even when expanded and contracted by temperature changes, the solar panel of the first embodiment reduces electrical connection deficiencies of the first photovoltaic battery cells 3 and the second photovoltaic battery cells 5.

In the interconnector 9, for example, the first to fourth detours 931 to 934 may be configured without being projected in the thickness-wise direction of the first and second electrodes 91 and 92. In this case, when the solar panel undergoes thermal expansion or contraction resulting from temperature changes, the interval of each first photovoltaic battery cell 3 and each second photovoltaic battery cell 5 changes so that the first and second detour portions 931 and 932 are accordingly deformed along a plane in the lateral direction and moved toward or away from each other. In the same manner, the third and fourth detour portions 933 and 934 are deformed along a plane in the lateral direction and moved toward or away from each other. When the first to fourth detour portions 931 to 934 each have a small width, the first to fourth detour portions 931 to 934 are easily deformed in the lateral direction. As a result, the load applied to the interconnector 9 when the interval of the first photovoltaic battery cell 3 and the second photovoltaic battery cell 5 changes is absorbed in a preferred manner. However, when the first to fourth detour portions 931 to 934 each have a small width, the electrical connection area of the first to fourth detour portions 931 to 934 is reduced. Consequently, the electrical connection area of the connection body 93 is reduced. This reduces the performance of electrical connection of the interconnector 9. In contrast, when the first to fourth detour portions 931 to 934 each have a large width, the electrical connection area of the connection body 93 is increased. However, the widthwise size impedes the deformation of the first to fourth detour portions 931 to 934 in the lateral direction. Thus, the load applied to the interconnector 9 cannot be absorbed sufficiently.

In the interconnector 9 of the solar panel of the first embodiment, the detour portion 93a, that is, the first to fourth detours 931 to 934, project at a substantially right angle in the thickness-wise direction of the first electrode 91 and the second electrode 92. Thus, as described above, the first and second detour portions 931 and 932 are flexed in the thickness-wise direction of the first and second detour portions 931 and 932 when moved toward or away from each other in the lateral direction. The same applies to the third and fourth detour portions 933 to 934. Thus, in the interconnector 9, even when the first to fourth detour portions 931 to 934 each have a relatively large width, flexing of the first to fourth detour portions 931 to 934 in the thickness-wise direction is not impeded. Thus, since the first and second detour portions 931 and 932 easily move toward or away from each other in the lateral direction and the third and fourth detour portions 933 and 934 easily move toward or away from each other in the lateral direction, the load applied to the interconnector 9 is absorbed in a preferred manner. Further, since the connection body 93 has a sufficient electrical connection area, the performance of electrical connection of the interconnector 9 is increased.

In the interconnector 9, the single copper plate 90 is bent to form the first electrode 91, the second electrode 92, and the connection body 93. Thus, in the solar panel, the interconnector 9 is easily formed.

In addition, in the interconnector 9, the first to fourth detours 931 to 934 project at a substantially right angle in the thickness-wise direction of the first and second electrodes 91 and 92. Thus, the first to fourth detour portions 931 to 934 are easily flexed in the thickness-wise direction of the first to fourth detour portions 931 to 934 in accordance with changes in the interval of the first photovoltaic battery cell 3 and the second photovoltaic battery cell 5.

The first and second electrodes 91 and 92 are connected to the first and second photovoltaic battery cells 3 and 5. Thus, in the interconnector 9, the connection body 93 projects toward the upper side of each of the front surfaces 3a and 5a of the first and second photovoltaic battery cells 3 and 5. In the solar panel, the recess 1c is formed in a portion of the rear surface 1b of the protection plate 1 that opposes the connection body 93. This obviates interference between the protection plate 1 and the connection body 93. Thus, when the solar panel is expanded and contracted by temperature changes, the first to fourth detour portions 931 to 934 are easily deformed as described above.

Additionally, in the interconnector 9, the first and second connection portions 935 and 936 are located in the recess 1c of the protection plate 1. This allows for easy positioning of the first and second connection portions 935 and 936 and the recess 1c and, in turn, allows for easy positioning of the interconnector 9 relative to the protection plate 1.

In the solar panel, the silicone resin 12 holds the entire interconnector 9, the right end of each first photovoltaic battery cell 3, and the left end of each second photovoltaic battery cell 5 in an encapsulated state. The silicone resin 12 is elastically deformed easily and not hardened even under a low-temperature environment. Thus, in the solar panel, the first to fourth detour portions 931 to 934 are deformed more easily when expanded or contracted by temperature changes than when the interconnector 9 is fixed in an encapsulated state only by the encapsulant 11 formed from EVA.

Further, in the solar panel, each first silicone resin 17a causes each first photovoltaic battery cell 3 to adhere to the back panel 13, and each second silicone resin 17b causes each second photovoltaic battery cell 5 to adhere to the back panel 13. This allows for easy positioning of each first photovoltaic battery cell 3 and each second photovoltaic battery cell 5 of the solar panel when manufactured. In addition, when the back panel 13 is expanded and contracted by temperature changes during manufacturing and use, each first photovoltaic battery cell 3 and each second photovoltaic battery cell 5 are movable so as to follow the back panel 13. Thus, displacement of each first photovoltaic battery cell 3 and each second photovoltaic battery cell 5 from the protection plate 1 is limited in the solar panel. This restricts situations in which the main portion 10a and the connection portions 10b of the shield 10 partially conceal the first photovoltaic battery cells 3 and the second photovoltaic battery cells 5 even when the solar panel is expanded and contracted by temperature changes.

Each first photovoltaic battery cell 3 and each second photovoltaic battery cell 5 adhere to the back panel 13 at the rear surface 3b and the rear surface 5b, respectively. Thus, even when the solar panel is viewed from the front surface 1a of the protection plate 1, each of the first and second silicone resins 17a and 17b are hidden and cannot be seen. This improves the aesthetic appeal of the solar panel.

### Second Embodiment

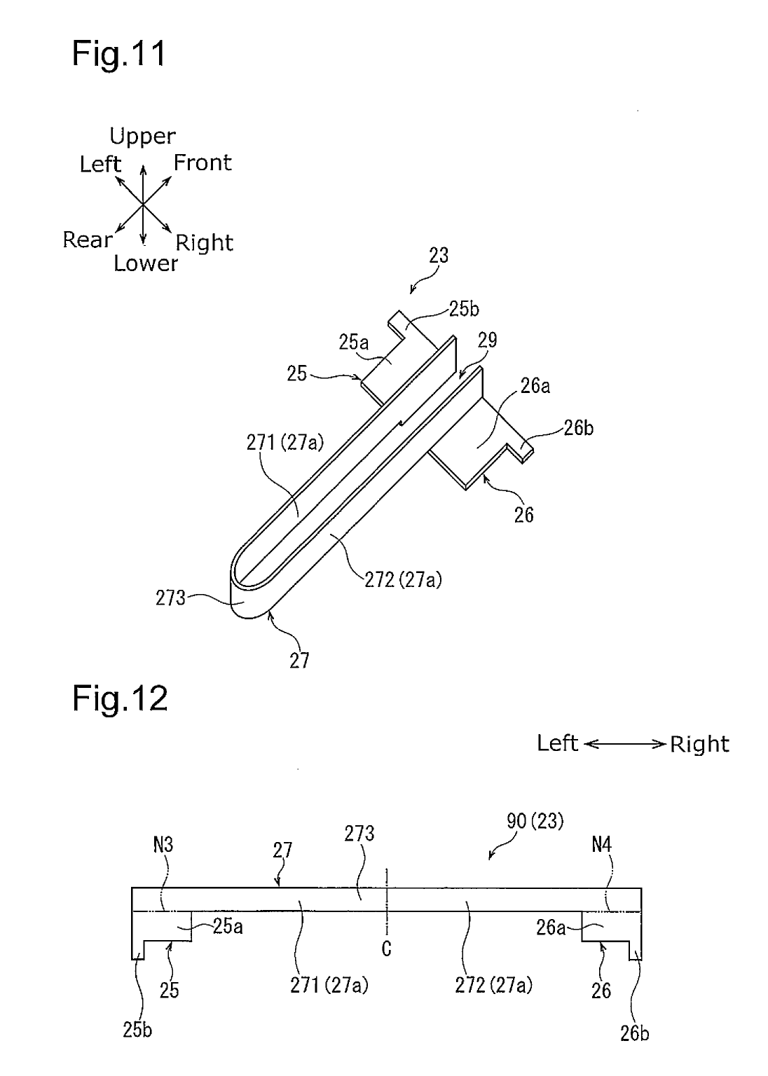

The solar panel of the second embodiment includes an interconnector 23 shown in FIG. 11 instead of the interconnector 9 in the solar panel of the first embodiment. The interconnector 23 includes a first electrode 25, a second electrode 26, and a connection body 27. In the same manner as the interconnector 9, the interconnector 23 is formed by bending a copper plate 90 shown in FIG. 12. Thus, the first electrode 25, the second electrode 26, and the connection body 27 are integrally formed.

More specifically, the copper plate 90 is first punched into the shape shown in the net diagram of FIG. 12. Then, valley-folding (bending) is performed at a substantially right angle at bent positions N3 and N4 shown by the double-dashed line. Subsequently, the copper plate 90 is bent to be substantially U-shaped so that the left end and right end of the copper plate 90, that is, the first electrode 25 and the second electrode 26, oppose each other with a peak formed at a center C in the lateral direction of the copper plate 90. This forms the interconnector 23 shown in FIG. 11.

The first electrode 25 is located at the left side of the interconnector 23. The second electrode 26 is located at the right side of the interconnector 23. The first electrode 25 includes a first base 25a, which extends in the front-to-rear direction of the interconnector 23, and a first contact 25b, which is integrated with the first base 25a and extended from the first base 25a toward the left side. The second electrode 26 includes a second base 26a, which extends in the front-to-rear direction of the interconnector 23, and a second contact 26b, which is integrated with the second base 26a and extended from the second base 26a toward the right side. The length in the front-to-rear direction of the first electrode 25 and the second electrode 26 is approximately one-half that of the first electrode 91 and the second electrode 92 of the interconnector 9.

The connection body 27 includes a detour portion 27a and a first connection portion 273 serving as a connection portion. The detour portion 27a includes a first detour portion 271 and a second detour portion 272. Valley-folding (bending) is performed at the bent position N3, which is shown in FIG. 12, so that the first detour portion 271 projects at a substantially right angle toward the upper side in the thickness-wise direction of the first electrode 25 and a front end of the first detour portion 271 is integrated with the first base 25a of the first electrode 25 as shown in FIG. 11. In the same manner as the first detour portion 931, the first detour portion 271 is a single piece having a predetermined width and extending toward a rear side of the interconnector 23.

Valley-folding (bending) is performed at the bent position N4, which is shown in FIG. 12, so that the second detour portion 272 projects at a substantially right angle toward the upper side in the thickness-wise direction of the second electrode 26 and a front side of the second detour portion 272 is integrated with the second base 26a of the second electrode 26 as shown in FIG. 11. The second detour portion 272 is spaced apart from a right end of the first detour portion 271 by a predetermined interval. The second detour portion 272 is a single piece having the same width as the first detour portion 271 and extending toward the rear side of the interconnector 23.

The first connection portion 273 is located at a rear end of the connection body 27. As described above, the copper plate 90 is curved to have a peak formed at the center C in the lateral direction of the copper plate 90 shown in FIG. 12. This forms the first connection portion 273. Thus, the first connection portion 273 is a single piece curved to have a semicircular shape and extended in the left and right directions toward the rear end of the first detour portion 271 and the rear end of the second detour portion 272. The first connection portion 273 is continuous with the rear ends of first and second distal ends 271a and 272a.

Thus, in the interconnector 23, the first electrode 25 and the second electrode 26 are connected by the connection body 27. This defines a void 29 at the middle of the interconnector 23. The void 29 functions as a separator that separates the first detour portion 271 and the first electrode 25 from the second detour portion 272 and the second electrode 26 in the lateral direction.

Although not illustrated in the drawings, in the same manner as the interconnector 9, the first electrode 25 of the interconnector 23 is connected to the first photovoltaic battery cell 3 so that the conductor of the first photovoltaic battery cell 3 is electrically connected to the first contact 25b. Further, the second electrode 26 is connected to the second photovoltaic battery cell 5 so that the conductor of the second photovoltaic battery cell 5 is electrically connected to the second contact 26b. Thus, in the solar panel, the interconnectors 23 electrically connect the first photovoltaic battery cells 3 to the adjacent second photovoltaic battery cells 5 in the lateral direction. The remaining structure of the solar panel of the second embodiment is the same as the solar panel of the first embodiment. Like or same reference numerals are given to those components that are the same as the corresponding components of the first embodiment and will not be described in detail.

When a change in temperature thermally contracts or expands the solar panels, the interval changes between the first photovoltaic battery cells 3 and the second photovoltaic battery cells 5. In such a case, in the connection body 27 of each interconnector 23, the first detour portion 271 and the second detour portion 272 are flexed in the thickness-wise direction of the first detour portion 271 and the second detour portion 272 and moved toward or away from each other in the lateral direction in the same manner as the connection body 93 of the interconnector 9. As a result, in the interconnector 23 of the solar panel, the first electrode 25 and the second electrode 26 are movable toward or away from each other while the deformation of the first and second detour portions 271 and 272 absorbs the load of the pressing force or the pulling force applied in the lateral direction by each first photovoltaic battery cell 3 or each second photovoltaic battery cell 5 when the solar panel thermally contracts or expands.

In particular, in the interconnector 23, the connection body 27 includes the single first detour portion 271, the single second detour portion 272, and the single first connection portion 273. Thus, the connection body 273 of the interconnector 23 has a simpler structure than the connection body 27 of the interconnector 9. This further facilitates manufacturing of the interconnector 23. The solar panel of the second embodiment also has the same advantages as the solar panel of the first embodiment.

### Third Embodiment

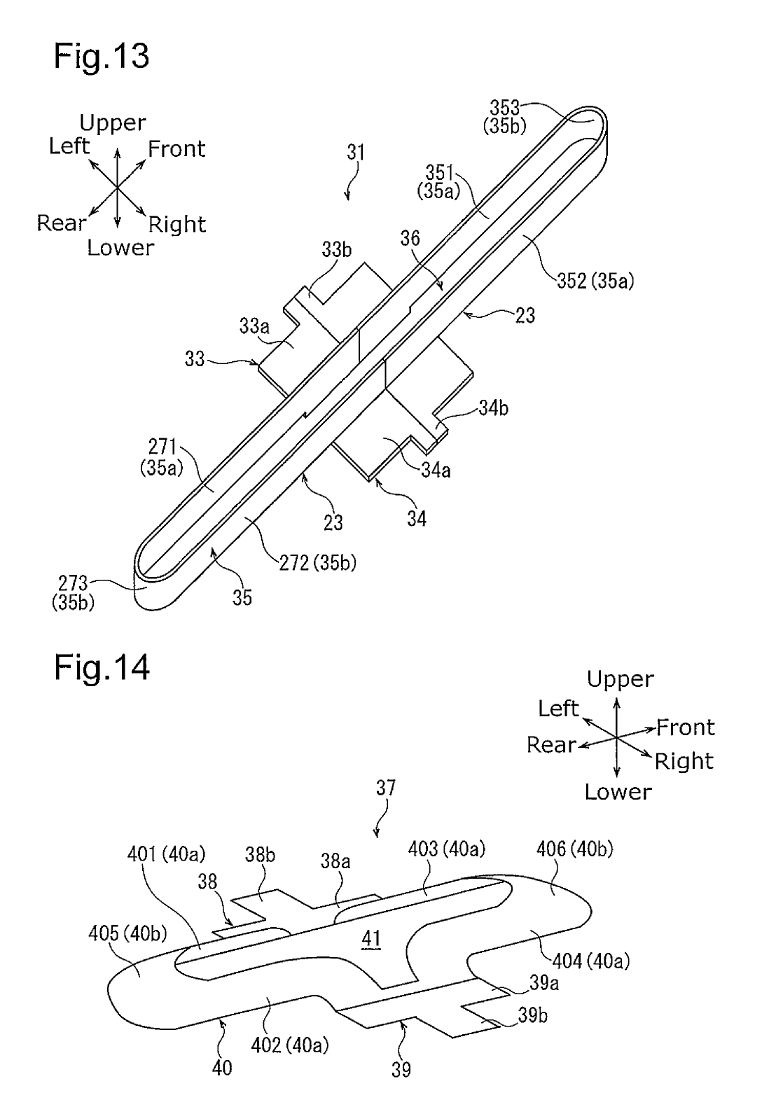

The solar panel of the third embodiment includes an interconnector 31 shown in FIG. 13 instead of the interconnector 9 in the solar panel of the first embodiment. The interconnector 31 is formed by arranging two interconnectors 23 to oppose to each other in the front-to-rear direction. The interconnector 31 includes a first electrode 33, a second electrode 34, and a connection body 35.

The first electrode 33 is located at a left side of the interconnector 31, and the second electrode 34 is located at a right side of the interconnector 31. The first electrode 33 includes a first base 33a, which extends in the front-to-rear direction of the interconnector 31, and a first contact 33b, which is integrated with the first base 33a and extended from the first base 33a toward the left side. The second electrode 34 includes a second base 34a, which extends in the front-to-rear direction of the interconnector 31, and a second contact 34b, which is integrated with the second base 34a and extended from the second base 34a toward the right side.

The connection body 35 includes a detour portion 35a and a connection portion 35b. The detour portion 35a includes the first detour portion 271, the second detour portion 272, a third detour portion 351, and a fourth detour portion 352. The connection portion 35b includes the first connection portion 273 and a second connection portion 353. In the interconnector 31, the front side of the first detour portion 271 is integrated with a rear side of the first base 33a, and the front side of the second detour portion 272 is integrated with a rear side of the second base 34a.

A rear side of the third detour portion 351 is integrated with a front side of the first base 33a, and a rear side of the fourth detour portion 352 is integrated with a front side of the second base 34a. The structure of the third detour portion 351, the fourth detour portion 352, and the second connection portion 353 is the same as the structure of the first detour portion 271, the second detour portion 272, and the first connection portion 273 except in that the structure is reversed in the front-to-rear direction. Thus, these parts will not be described in detail.

In the interconnector 31, the first electrode 33 and the second electrode 34 are connected by the connection body 35. Further, the middle of the interconnector 31 defines a void 36 extending in the front-to-rear direction and the lateral direction. The void 36 functions as a separator that separates the first detour portion 271, the first electrode 33, and the third detour portion 351 from the second detour portion 272, the second electrode 34, and the fourth detour portion 352 in the lateral direction.

In the same manner as the interconnector 9, the first electrode 33 of the interconnector 31 is connected to the first photovoltaic battery cell 3 so that the conductor of the first photovoltaic battery cell 3 and the first contact 33b are electrically connected. Further, the second electrode 34 is connected to the second photovoltaic battery cell 5 so that the conductor of the second photovoltaic battery cell 5 and the second contact 34b are electrically connected. Thus, in the solar panel, the interconnector 31 electrically connects the first photovoltaic battery cell 3 and the second photovoltaic battery cell 5 that are adjacent to each other in the lateral direction. The remaining structure of the solar panel of the third embodiment is the same as the solar panel of the first embodiment.

When a change in temperature thermally contracts or expands the solar panel, the interval changes between the first photovoltaic battery cell 3 and the second photovoltaic battery cell 5 so that the first detour portion 271, the second detour portion 272, the third detour portion 351, and the fourth detour portion 352 are accordingly flexed in the thickness-wise direction in the interconnector 31 in the same manner as the interconnector 9. In the interconnector 31 of the solar panel, this allows the interval between the first electrode 33 and the second electrode 34 to be changed. Accordingly, the solar panel of the third embodiment also has the same advantages as the solar panel of the first embodiment.

The two interconnectors 23 are opposed to each other in the front-to-rear direction to form the interconnector 31. This allows the interconnector 31 to be easily formed.

### Fourth Embodiment

The solar panel of the fourth embodiment includes an interconnector 37 shown in FIG. 14 instead of the interconnector 9 of the solar panel of the first embodiment. In the same manner as the interconnectors 9 and 23, the interconnector 37 is formed by bending a copper plate 90 that has been punched into a predetermined shape.

The interconnector 37 includes a first electrode 38, a second electrode 39, and a connection body 40. The first electrode 38, the second electrode 39, and the connection body 40 are integrally formed.

The first electrode 38 is located at a left side of the interconnector 37, and the second electrode 39 is located at a right side of the interconnector 37. The first electrode 38 includes a first base 38a, which extends in the front-to-rear direction of the interconnector 37, and a first contact 38b, which is integrated with the first base 38a and extended from the first base 38a toward the left side. The second electrode 39 includes a second base 39a, which extends in the front-to-rear direction of the interconnector 37, and a second contact 39b, which is integrated with the second base 39a and extended from the second base 39a toward the right side.

The connection body 40 includes a detour portion 40a and a connection portion 40b. The detour portion 40a includes first to fourth detour portions 401 to 404. The connection portion 40b includes a first connection portion 405 and a second connection portion 406. The first detour portion 401 is inclined at a certain angle toward the right of the interconnector 37 and extended upward from the first electrode 38. A front end of the first detour portion 401 is integrated with the first base 38a of the first electrode 38. The first detour portion 401 is a single piece having a predetermined width and extending toward a rear side of the interconnector 37.

The second detour portion 402 is inclined at a certain angle toward the left of the interconnector 37 and extended upward from the second electrode 39. A front end of the second detour portion 402 is integrated with the second base 39a of the second electrode 39. The second detour portion 402 is a single piece having the same width as the first detour portion 401 and extending toward the rear side of the interconnector 37.

In the same manner as the first detour portion 401, the third detour portion 403 is inclined and extended upward from the first electrode 38. A rear end of the third detour portion 403 is integrated with the first base 38a of the first electrode 38. The third detour portion 403 is a single piece having the same width as the first detour portion 401 and extending toward a front side of the interconnector 37.

In the same manner as the second detour portion 402, the fourth detour portion 404 is inclined and extended upward from the second electrode 39. A rear end of the fourth detour portion 404 is integrated with the second base 39a of the second electrode 39. The fourth detour portion 404 is a single piece having the same width as the first detour portion 401 and extending toward the front side of the interconnector 37.

The first connection portion 405 is located between the rear end of the first detour portion 401 and the rear end of the second detour portion 402, that is, located at the rear end of the connection body 40. The first connection portion 405 is a single piece extending in the lateral direction. The first connection portion 405 is curved so that upper portions are inclined further toward the front of the interconnector 37. Further, the first connection portion 405 is continuous with the rear end of the first detour portion 401 and the rear end of the second detour portion 402. Thus, the first detour portion 401 and the second detour portion 402 are connected by the first connection portion 405.

The second connection portion 406 is located between the front end of the third detour portion 403 and the front end of the fourth detour portion 404, that is, located at a front end of the connection body 40. The second connection portion 406 is a single piece extending in the lateral direction. The second connection portion 406 is curved so that upper portions are inclined further toward the front of the interconnector 37. Further, the second connection portion 406 is continuous with the front end of the third detour portion 403 and the front end of the fourth detour portion 404. Thus, the third detour portion 403 and the fourth detour portion 404 are connected by the second connection portion 406.

In the interconnector 37, the first electrode 38 and the second electrode 39 are connected by the connection body 40 so that the first electrode 38 and the second electrode 39 are electrically connected by the connection body 40, that is, by the first to fourth detour portions 401 to 404 and the first and second connection portions 405 and 406. Further, the connection body 40 connects the first electrode 38 to the second electrode 39 as described above to define a void 41 that extends in the front-to-rear direction and the lateral direction at the middle of the interconnector 37. The void 41 functions as a separator that separates the first detour portion 401, the first electrode 38, and the third detour portion 403 from the second detour portion 402, the second electrode 39, and the fourth detour portion 404 in the lateral direction.

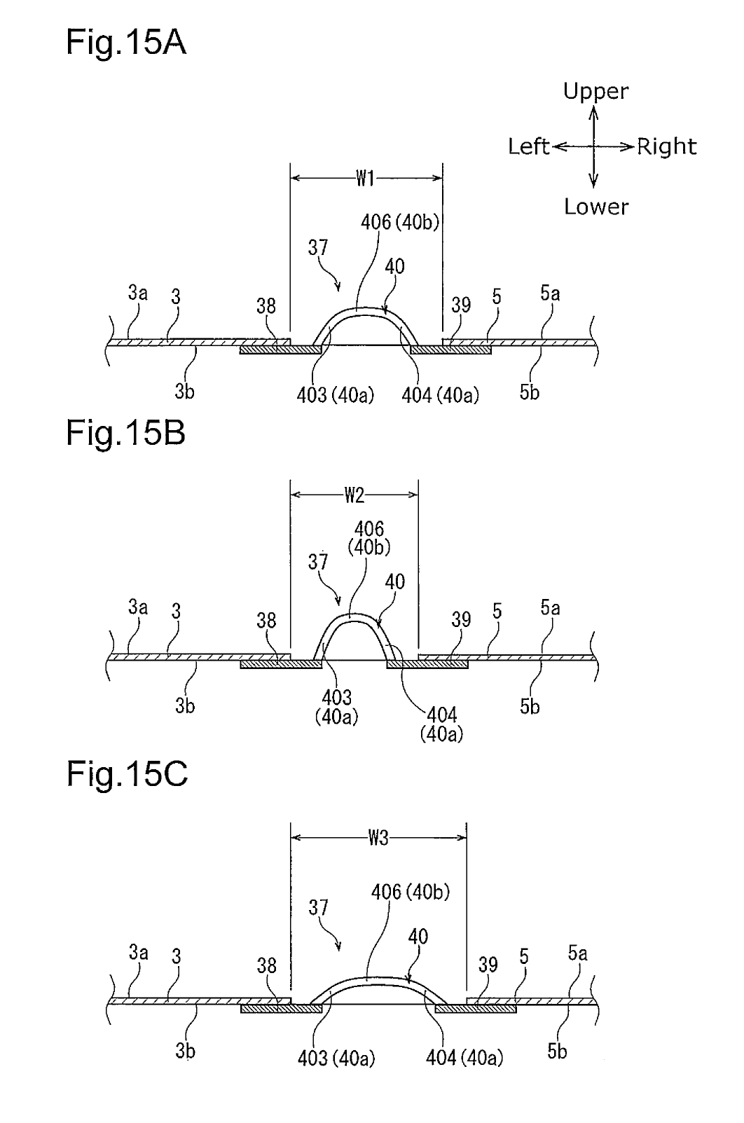

As shown in FIGS. 15A to 15C, in the solar panel, the interconnector 37 electrically connects the first photovoltaic battery cell 3 to the adjacent second photovoltaic battery cell 5 in the lateral direction. In the same manner as the first and second electrodes 91 and 92 of the interconnector 9, the first and second electrodes 38 and 39 of the interconnector 37 are respectively connected to the corresponding first and second photovoltaic battery cells 3 and 5. Further, in the interconnector 37, the first and second electrodes 38 and 39 are respectively connected to the first and second photovoltaic battery cells 3 and 5 so that the connection body 40 projects upward from the front surfaces 3a and 5a of the first and second photovoltaic battery cells 3 and 5. To facilitate understanding, the form of the interconnector 37 is simplified in FIGS. 15A to 15C. Further, the protection plate 1 is not shown. The other structures of the solar panel of the fourth embodiment are the same as the solar panel of the first embodiment.

In the interconnector 37 of the solar panel, the first to fourth detour portions 401 to 404 of the connection body 40 are inclined and extended upward from the first electrode 38 and the second electrode 39. Thus, in the solar panel, when a change in temperature causes contraction that narrows the interval W1 between the first photovoltaic battery cell 3 and the second photovoltaic battery cell 5 shown in FIG. 15A to the interval W2 shown in FIG. 15B, the third detour portion 403 of the connection body 40 is accordingly flexed in the thickness-wise direction so that the inclination angle relative to the first electrode 38 increases, and the fourth detour portion 404 of the connection body 40 is accordingly flexed in the thickness-wise direction so that the inclination angle relative to the second electrode 39 increases. Further, when the third and fourth detour portions 403 and 404 are deformed, the second connection portion 406 is accordingly flexed. Although not illustrated in the drawings, the first detour portion 401 is flexed in the same manner as the third detour portion 403, and the second detour portion 402 is flexed in the same manner as the fourth detour portion 404. In addition, the first connection portion 405 is flexed in the same manner as the second connection portion 406. Thus, the connection body 40 moves the first electrode 38 and the second electrode 39 toward each other in the lateral direction. As a result, in the interconnector 37 of the solar panel, the first electrode 38 and the second electrode 39 are movable toward each other while the deformation of the first to fourth detour portions 401 to 404 and the first and second connection portions 405 and 406 absorbs the load applied when the solar panel contracts.

Further, in the solar panel, when a change in temperature causes expansion that widens the interval W1 between the first photovoltaic battery cell 3 and the second photovoltaic battery cell 5 shown in FIG. 15A to the interval W3 shown in FIG. 15C, the third detour portion 403 of the connection body 40 is accordingly flexed in the thickness-wise direction so that the inclination angle relative to the first electrode 38 decreases, and the fourth detour portion 404 of the connection body 40 is accordingly flexed in the thickness-wise direction so that the inclination angle relative to the second electrode 39 decreases. Further, when the third and fourth detour portions 403 and 404 are deformed, the second connection portion 406 is accordingly flexed. The same applies to the first detour portion 401, the second detour portion 402, and the first connection portion 405. Thus, the connection body 40 moves the first electrode 38 and the second electrode 39 away from each other in the lateral direction. As a result, in the interconnector 37 of the solar panel, the first electrode 38 and the second electrode 39 are movable away from each other while the deformation of the first to fourth detour portions 401 to 404 and the first and second connection portions 405 and 406 absorbs the load applied when the solar panel expands. Accordingly, the solar panel of the fourth embodiment also has the same advantages as the solar panel of the first embodiment.

Although the present invention has been described as above according to the first to fourth embodiments, the present invention is not limited to the first to fourth embodiments. It should be apparent to those skilled in the art that the present invention may be embodied in many other specific forms without departing from the spirit or scope of the invention. Particularly, it should be understood that the present invention may be embodied in the following forms.

For example, in the solar panel of the first embodiment, the conductors may be respectively arranged on the front surface 3a of each first photovoltaic battery cell 3 and the front surface 5a of the second photovoltaic battery cell 5 so that the first electrode 91 is connected to the front surface 3a of each first photovoltaic battery cell 3 and the second electrode 92 is connected to the front surface 5a of each second photovoltaic battery cell 5. The same applies to the solar panels of the second to fourth embodiments.

In the solar panel of the first embodiment, the detour portion 93a may include only the first and second detour portions 931 and 932, and the connection portion 93b may include only the first connection portion 935.

The interconnector 9 may include a plurality of first to fourth detour portions 931 to 934 and a plurality of first and second connection portions 935 and 936. The same applies to the interconnectors 23, 31, and 37.

In the interconnector 9, the first and second connection portions 935 and 936 are both arranged in the recess 1c of the protection plate 1. Instead, only one of the first and second connection portions 935 and 936 may be arranged in the recess 1c of the protection plate 1. Further, a member that is arranged in the recess 1c of the protection plate 1 may be coupled to the first and second connection portions 935 and 936. The same applies to the interconnectors 23, 31, and 37.

In the interconnector 9, the first to fourth detour portions 931 to 934 may project downward from the first and second electrodes 91 and 92 in the thickness-wise direction. In this case, in the solar panel of the first embodiment, instead of arranging the recess 1c in the protection plate 1, the thickness of the back panel 13 may be increased to form a recess corresponding to the recess 1c in the front surface 13a of the back panel 13. In this manner, when the recess 1c is not arranged in the protection plate 1, a protection cover may be formed by, for example, a translucent protection film instead of the protection plate 1. The same applies to the solar panels of the second to fourth embodiments.

In the solar panel of the first embodiment, the recess 1c does not have to be formed in the protection plate 1, and the recess corresponding to the recess 1c does not have to be formed in the back panel 13. The same applies to the solar panels of the second to fourth embodiments.

Each first silicone resin 17a may cause the front surface 3a of each first photovoltaic battery cell 3 to adhere to the rear surface 1b of the protection plate 1, and each second silicone resin 17b may cause the front surface 5a of each second photovoltaic battery cell 5 to adhere to the rear surface 1b of the protection plate 1. In this case, it is preferred that each of the first and second silicone resins 17a and 17b be translucent to limit decreases in the power generation efficiency.

In the solar panel of the first embodiment, the first and second silicone resins 17a and 17b do not have to be arranged. The same applies to the solar panels of the second to fourth embodiments.

The solar panels of the first to fourth embodiments do not have to be flat and may be curved.

The present invention is applicable to a solar panel mounted on a vehicle roof or a solar panel used for any of a variety of photovoltaic systems.

Therefore, the present examples and embodiments are to be considered as illustrative and not restrictive and the invention is not to be limited to the details given herein, but may be modified within the scope and equivalence of the appended claims.

1. An interconnector configured to connect a first photovoltaic battery cell and a second photovoltaic battery cell that are adjacent to each other in a first direction in a manner allowing for electrical connection of the first photovoltaic battery cell and the second photovoltaic battery cell, the interconnector comprising:
a first electrode configured to be connected to the first photovoltaic battery cell;
a second electrode configured to be connected to the second photovoltaic battery cell; and
a connection body that connects the first electrode and the second electrode, wherein
a second direction is defined orthogonal to the first direction, and a first side and a second side are defined in the second direction,
the first electrode, the second electrode, and the connection body are integrally formed by bending a single metal plate,
the connection body includes a detour portion that projects in a thickness-wise direction of the first electrode and the second electrode and a connection portion that extends in the first direction and is connected to the detour portion,
the detour portion includes a first detour portion that is electrically connected to the first electrode and extended toward the first side in the second direction and a second detour portion that is electrically connected to the second electrode and extended toward the first side in the second direction, and
the connection portion includes a first connection portion that connects the first detour portion and the second detour portion.

2. The interconnector according to claim 1, wherein
the detour portion further includes a third detour portion that is electrically connected to the first electrode and extended toward the second side in the second direction and a fourth detour portion that is electrically connected to the second electrode and extended toward the second side in the second direction, and
the connection portion further includes a second connection portion that connects the third detour portion and the fourth detour portion.

3. The interconnector according to claim 1, wherein the detour portion projects at a substantially right angle in the thickness-wise direction.

4. The interconnector according to claim 1, wherein
the detour portion is inclined and extended in the thickness-wise direction, and
the connection portion is curved and connected to the detour portion.

5. A solar panel comprising:
a first photovoltaic battery cell;
a second photovoltaic battery cell adjacent to the first photovoltaic battery cell in a first direction;
an interconnector configured to connect the first photovoltaic battery cell and the second photovoltaic battery cell to each other in a manner allowing for electrical connection of the first photovoltaic battery cell and the second photovoltaic battery cell;
a protection cover that is translucent from a front surface to a rear surface;
a back cover; and
an encapsulant that encapsulates and fixes the first photovoltaic battery cell, the second photovoltaic battery cell, and the interconnector between the protection cover and the back cover;
wherein the interconnector includes:
a first electrode configured to be connected to the first photovoltaic battery cell;
a second electrode configured to be connected to the second photovoltaic battery cell; and
a connection body that connects the first electrode and the second electrode, wherein
a second direction is defined orthogonal to the first direction, and a first side and a second side are defined in the second direction,
the first electrode, the second electrode, and the connection body are integrally formed by bending a single metal plate,
the connection body includes a detour portion that projects in a thickness-wise direction of the first electrode and the second electrode and a connection portion that extends in the first direction and is connected to the detour portion,
the detour portion includes a first detour portion that is electrically connected to the first electrode and extended toward the first side in the second direction and a second detour portion that is electrically connected to the second electrode and extended toward the first side in the second direction, and
the connection portion includes a first connection portion that connects the first detour portion and the second detour portion.

6. The solar panel according to claim 5, wherein the protection cover or the back cover includes a recess at a location opposing the connection body, and the recess is recessed to extend away from the connection body.

7. The solar panel according to claim 6, wherein the connection portion is located in the recess.

8. The solar panel according to claim 5, wherein the encapsulant includes a silicone resin that surrounds the interconnector and elastically deforms to hold the encapsulated interconnector.

9. The solar panel according to claim 5, wherein
the encapsulant includes a first cutout opposing the first photovoltaic battery cell and a second cutout opposing the second photovoltaic battery cell,
the first cutout receives a first adhesive that causes the protection cover or the back cover to adhere to the first photovoltaic battery cell and positions the first photovoltaic battery cell, and
the second cutout receives a second adhesive that causes the protection cover or the back cover to adhere to the second photovoltaic battery cell and positions the second photovoltaic battery cell.
